(19) United States
(12) Patent Application Publication
(10) Pub. No.: US 2024/0266240 A1
(43) Pub. Date: Aug. 8, 2024

(54) MODULE

(71) Applicant: Murata Manufacturing Co., Ltd., Kyoto-fu (JP)

(72) Inventors: Akio KATSUBE, Nagaokakyo-shi, Kyoto-fu (JP); Hideki SHINKAI, Nagaokakyo-shi, Kyoto-fu (JP)

(21) Appl. No.: 18/640,076

(22) Filed: Apr. 19, 2024

Related U.S. Application Data
(63) Continuation of application No. PCT/JP2022/040142, filed on Oct. 27, 2022.

(30) Foreign Application Priority Data
Nov. 1, 2021 (JP) 2021-178512

(51) Int. Cl. H01L 23/31; H01L 21/56; H01L 23/00; H01L 23/544; H01L 23/552; H01L 25/065; H01L 25/16; H03H 3/02; H03H 3/08; H03H 9/02; H03H 9/05; H03H 9/08; H03H 9/10

(52) U.S. Cl. CPC H01L 23/3185; H01L 21/561; H01L 23/552; H03H 3/02; H03H 3/08; H03H 9/02086; H03H 9/02913; H03H 9/0523; H03H 9/0542; H03H 9/059; H03H 9/08; H03H 9/1042; H03H 9/1085; H01L 23/544; H01L 24/16; H01L 25/0655; H01L 25/16; H01L 2223/54486; H01L 2224/16227

(57) ABSTRACT

A module includes a substrate, a first component, and a sealing resin. The substrate is provided with a first surface. The first component is mounted on the first surface. The first component is sealed with the sealing resin at least from a lateral side. The first component includes a projecting portion. The projecting portion projects from the sealing resin on a side opposite to a side of the substrate.

### CROSS REFERENCE TO RELATED APPLICATION

This is a continuation of International Application No. PCT/JP2022/040142 filed on Oct. 27, 2022 which claims priority from Japanese Patent Application No. 2021-178512 filed on Nov. 1, 2021. The contents of these applications are incorporated herein by reference in their entireties.

### BACKGROUND OF THE DISCLOSURE

### Field of the Disclosure

The present disclosure relates to a module.

### Description of the Related Art

Japanese Patent Laid-Open No. 2010-192653 (PTL 1) and Japanese Patent Laid-Open No. 2004-208326 (PTL 2) each disclose a construction of a module.

The module described in PTL 1 includes a first circuit board, a semiconductor component and an electronic component, a molded part, and a coating. The first circuit board is disposed such that an interconnection electrode is exposed at a side end face. The semiconductor component and the electronic component are mounted on the first circuit board. The molded part is composed of resin and covers at least a part of the semiconductor component and the electronic component. A part of the semiconductor component is exposed and the remainder thereof is covered with the molded part.

The module described in PTL 2 includes an interconnection pattern, a surface acoustic wave element, and a thermosetting resin composition. The surface acoustic wave element is mounted on the interconnection pattern. The surface acoustic wave element is sealed with the thermosetting resin composition. A surface of the surface acoustic wave element opposite to a functional portion thereof and an upper surface of the thermosetting resin composition are flush with each other.

PTL 1: Japanese Patent Laid-Open No. 2010-192653

PTL 2: Japanese Patent Laid-Open No. 2004-208326

### BRIEF SUMMARY OF THE DISCLOSURE

In a conventional module, performance to radiate heat generated from a component mounted on a substrate may be enhanced by exposing a part of the component through a sealing resin. There is a room, however, for further improvement in performance to radiate heat generated from the component.

The present disclosure was made in view of the problem above, and a possible benefit thereof is to provide a module capable of achieving further improvement in performance to radiate heat generated from a component mounted on a substrate.

A module based on the present disclosure includes a substrate, a first component, and a sealing resin. The substrate is provided with a first surface. The first component is mounted on the first surface. The first component is sealed with the sealing resin at least from a lateral side. The first component includes a projecting portion. The projecting portion projects from the sealing resin on a side opposite to a side of the substrate.

According to the present disclosure, the component mounted on the substrate includes the projecting portion that projects from the sealing resin, so that an area of a portion of the surface of the component that is exposed through the sealing resin increases and performance to radiate heat generated from the component can further be improved.

### BRIEF DESCRIPTION OF THE SEVERAL VIEWS OF THE DRAWINGS

FIG. 1 is a plan view showing a module according to a first embodiment of the present disclosure.

FIG. 2 is a cross-sectional view of the module in FIG. 1, along a direction shown with an arrow II-II.

FIG. 3 is a schematic perspective view showing the module according to the first embodiment of the present disclosure.

FIG. 4 is a partial cross-sectional view showing a construction in a region IV in FIG. 2.

FIG. 5 is a cross-sectional view showing a state in which a substrate assembly is prepared in a method of manufacturing the module according to the first embodiment of the present disclosure.

FIG. 6 is a cross-sectional view showing a state in which a first component and the like are mounted on the substrate assembly in the method of manufacturing the module according to the first embodiment of the present disclosure.

FIG. 7 is a cross-sectional view showing a state in which a sealing resin is arranged on a first surface of the substrate assembly in the method of manufacturing the module according to the first embodiment of the present disclosure.

FIG. 8 is a cross-sectional view showing a state in which the sealing resin and the first component are being ground in the method of manufacturing the module according to the first embodiment of the present disclosure.

FIG. 9 is a cross-sectional view showing a construction in a state in which the sealing resin and the first component have been ground in the method of manufacturing the module according to the first embodiment of the present disclosure.

FIG. 10 is a cross-sectional view showing a state in which a surface of the sealing resin is further being ground away by laser in the method of manufacturing the module according to the first embodiment of the present disclosure.

FIG. 11 is a cross-sectional view showing a state in which a marking portion is being provided in the surface of the sealing resin in the method of manufacturing the module according to the first embodiment of the present disclosure.

FIG. 12 is a cross-sectional view showing a state in which the substrate assembly is being diced in the method of manufacturing the module according to the first embodiment of the present disclosure.

FIG. 13 is a plan view showing a state in which the module on which a shield film is yet to be formed is being moved in the method of manufacturing the module according to the first embodiment of the present disclosure.

FIG. 14 is a cross-sectional view of a movement step in FIG. 13, along a direction shown with an arrow XIV-XIV.

FIG. 15 is a cross-sectional view showing the movement step in an example where the marking portion is formed of ink in the method of manufacturing the module according to the first embodiment of the present disclosure.

FIG. 16 is a cross-sectional view showing a module according to a second embodiment of the present disclosure.

FIG. 17 is a partial cross-sectional view showing a construction in a region XVII in FIG. 16.

FIG. 18 is a partial cross-sectional view of a module according to a modification of the second embodiment of the present disclosure.

FIG. 19 is a cross-sectional view showing a wet blasting step after a grinding step in a method of manufacturing the module according to the second embodiment of the present disclosure.

FIG. 20 is a plan view showing a module according to a third embodiment of the present disclosure.

FIG. 21 is a cross-sectional view of the module in FIG. 20, along a direction shown with an arrow XXI-XXI.

FIG. 22 is a cross-sectional view showing a module according to a fourth embodiment of the present disclosure.

FIG. 23 is a cross-sectional view showing a module according to a fifth embodiment of the present disclosure.

FIG. 24 is a cross-sectional view showing a module according to a modification of the fifth embodiment of the present disclosure.

FIG. 25 is a cross-sectional view showing a module according to a sixth embodiment of the present disclosure.

FIG. 26 is a cross-sectional view showing a module according to a seventh embodiment of the present disclosure.

FIG. 27 is a cross-sectional view showing an exemplary assembly used in manufacturing of the module according to the seventh embodiment of the present disclosure.

### DETAILED DESCRIPTION OF THE DISCLOSURE

A module according to each embodiment of the present disclosure will be described below with reference to the drawings. In the description of the embodiment below, the same or corresponding elements in the drawings have the same reference characters allotted and description thereof will not be repeated.

### First Embodiment

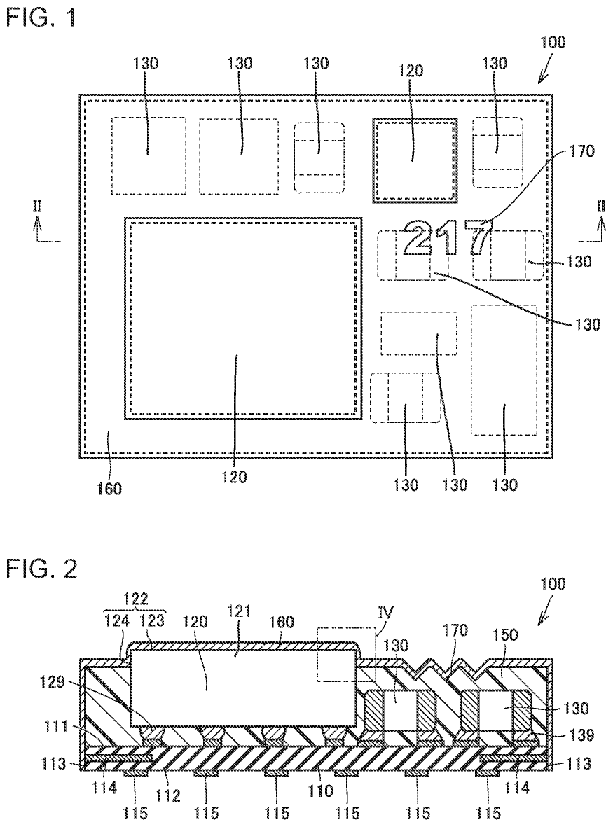

FIG. 1 is a plan view showing a module according to a first embodiment of the present disclosure. FIG. 2 is a cross-sectional view of the module in FIG. 1, along a direction shown with an arrow II-II. As shown in FIGS. 1 and 2, a module 100 includes a substrate 110, a first component 120, a plurality of second components 130, a sealing resin 150, a shield film 160, and a marking portion 170.

Substrate 110 is specifically a circuit board. Substrate 110 is provided with a first surface 111, a second surface 112, and a peripheral side surface 113. Second surface 112 is located opposite to first surface 111. Peripheral side surface 113 connects first surface 111 and second surface 112 to each other. Substrate 110 further includes a ground electrode 114 and an external terminal 115. Ground electrode 114 extends from the inside of substrate 110 toward peripheral side surface 113 and is exposed at peripheral side surface 113. External terminal 115 is located on second surface 112.

First component 120 is mounted on first surface 111 with a solder bump 129 being interposed. A plurality of first components 120 may be mounted on first surface 111. First component 120 is specifically an electronic component. Examples of first component 120 include a surface acoustic wave filter, a bulk acoustic wave filter, an integrated circuit (IC) chip, or the like.

First component 120 is substantially in a shape of a parallelepiped. First component 120 includes a projecting portion 121. Projecting portion 121 will be described later.

When first component 120 is a surface acoustic wave filter, a main material for first component 120 is, for example, Si, lithium tantalate (LiTaO₃), or lithium niobate LiNbO₃. When first component 120 is a bulk acoustic wave filter, a main material for first component 120 is, for example, Si. When first component 120 is an IC chip, a main material for first component 120 is, for example, Si or GaAs. Si, GaAs, LiTaO₃, and LiNbO₃ have thermal conductivities [W/(m·K)] of 163, 54, 8.8, and 38, respectively. The main material for first component 120 may be a polycrystalline body or an amorphous body such as glass.

The plurality of second components 130 are mounted on first surface 111 with solder 139 being interposed. Second component 130 is specifically an electronic component, and it is, for example, a passive component like a chip such as a capacitor or an inductor. Second component 130 may be a surface acoustic wave filter or an IC relatively small in amount of heat generation.

Sealing resin 150 is provided on first surface 111. First component 120 is sealed with sealing resin 150 at least from a lateral side. Second component 130 is sealed with sealing resin 150 so as not to be exposed through sealing resin 150.

A material for sealing resin 150 contains at least a resin component. The resin component is, for example, epoxy resin, phenol resin, or a mixture thereof. The epoxy resin and the phenol resin have thermal conductivities [W/(m·K)] of 0.3 and 0.21, respectively.

The material for sealing resin 150 may further contain a filler. The filler may be a spherical filler, a filler in an indefinite shape, or a mixture thereof. Examples of the filler include SiO₂ or Al₂O₃. SiO₂ and Al₂O₃ have thermal conductivities [W/(m·K)] of 1.4 and 36, respectively.

The thermal conductivity of the material for sealing resin 150 is, for example, not lower than 0.6 [W/(m·K)] and not higher than 1.1 [W/(m·K)]. In an example where the material contains the resin component and the filler, the thermal conductivity of the material can be adjusted based on a content of the filler. The main material for first component 120 is higher in thermal conductivity than the material for sealing resin 150.

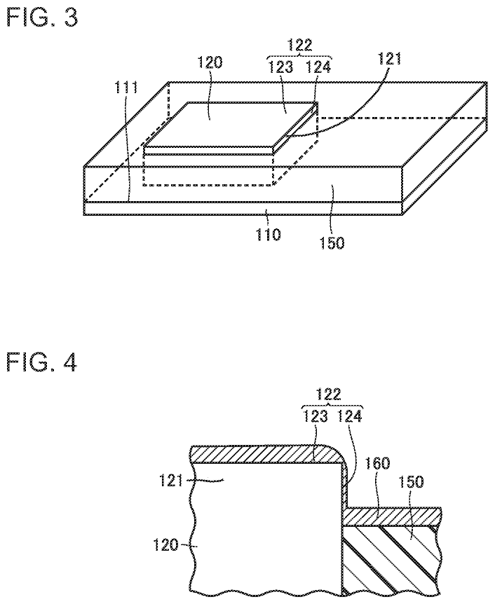

Projecting portion 121 of first component 120 will now be described. FIG. 3 is a schematic perspective view showing the module according to the first embodiment of the present disclosure. FIG. 3 schematically shows substrate 110, first component 120, and sealing resin 150. FIG. 4 is a partial cross-sectional view showing a construction in a region IV in FIG. 2.

As shown in FIGS. 1 to 4, projecting portion 121 projects from sealing resin 150 on the side opposite to substrate 110. Projecting portion 121 is substantially in a shape of a parallelepiped. Projecting portion 121 is provided with an outer edge portion 122. Outer edge portion 122 is provided with a planar portion 123 and a peripheral side portion 124 when viewed in a cross-section of projecting portion 121 along a plane perpendicular to first surface 111. Planar portion 123 is a surface of first component 120 that faces the side opposite to substrate 110. Peripheral side portion 124 is located along an outer edge of planar portion 123 while it is connected to planar portion 123. Peripheral side portion 124 extends in a direction substantially orthogonal to first surface 111.

Shield film 160 is made of metal and covers first component 120 and sealing resin 150. Shield film 160 is in contact with projecting portion 121. Shield film 160 further extends toward peripheral side surface 113 of substrate 110 and is in contact with peripheral side surface 113. Shield film 160 is in contact with ground electrode 114.

Shield film 160 may be formed by layering of a plurality of layers. In this case, the number of layers that form shield film 160 is not particularly limited. A total thickness of shield film 160 is, for example, not smaller than 1 [μm] and not larger than 20 [μm]. From a point of view of heat radiation performance, shield film 160 may be large in thickness, because a cross-sectional area of a heat transfer path in transfer of heat in a direction orthogonal to a direction of thickness of shield film 160 is large. From a point of view of a lower profile of module 100, shield film 160 may be small in thickness.

Of shield film 160 located on outer edge portion 122 of projecting portion 121, shield film 160 located on peripheral side portion 124 is smaller in thickness than shield film 160 located on planar portion 123. Shield film 160 located at a boundary portion between planar portion 123 and peripheral side portion 124 (that is, a corner portion of projecting portion 121) is smallest in thickness in shield film 160 located on outer edge portion 122 of projecting portion 121. Such a shape of shield film 160 is attributed to a method of forming shield film 160, and details of the method of forming the shield film will be described later.

Shield film 160 is made of metal. Shield film 160 contains an alloy containing at least one element selected from among Ti, Cr, Co, Ni, Fe, Cu, Ag, and Au. Ti, Cr, Co, Ni, Fe, Cu, Ag, and Au have thermal conductivities [W/(m·K)] of 22, 90, 99, 90, 53, 398, 427, and 315, respectively. Shield film 160 may contain stainless steel. Examples of stainless steel include SUS304, SUS405, or the like. SUS304 and SUS405 have thermal conductivities [W/(m·K)] of 16 and 27, respectively. The alloy contained in shield film 160 is higher in thermal conductivity than the material for sealing resin 150. Heat is thus more readily transferred from projecting portion 121 to shield film 160, and heat radiated from projecting portion 121 is further more readily radiated from shield film 160 to the outside.

Marking portion 170 is provided as being visually recognizable at a position different from first component 120 when module 100 is viewed from a side of first surface 111. Marking portion 170 is visually recognizable as a character, a graphics, or a sign. Marking portion 170 may be, for example, a two-dimensional code readable as a graphics by a prescribed device. Marking portion 170 is used for identification of a product name, a direction, a production lot, or a production history of module 100 by a manufacturer or a user of module 100.

Marking portion 170 is located in a portion of sealing resin 150 which is in contact with shield film 160 and faces the side opposite to substrate 110. Marking portion 170 is composed of a plurality of recesses in sealing resin 150 and shield film 160 is located along the plurality of recesses. Marking portion 170 is visually recognizable owing to light reflected by projections and recesses in shield film 160 located along the plurality of recesses in sealing resin 150. Alternatively, marking portion 170 may be formed of ink composed of epoxy resin or the like provided on sealing resin 150. In an example where marking portion 170 is formed of ink, it has a thickness, for example, of 10 [μm]. In this case, marking portion 170 is visually recognizable when shield film 160 is translucent.

Furthermore, marking portion 170 may directly be provided on shield film 160. In this case, marking portion 170 may be composed of a plurality of recesses provided in shield film 160 or formed of ink composed of epoxy resin or the like provided on shield film 160. Module 100 does not have to include marking portion 170.

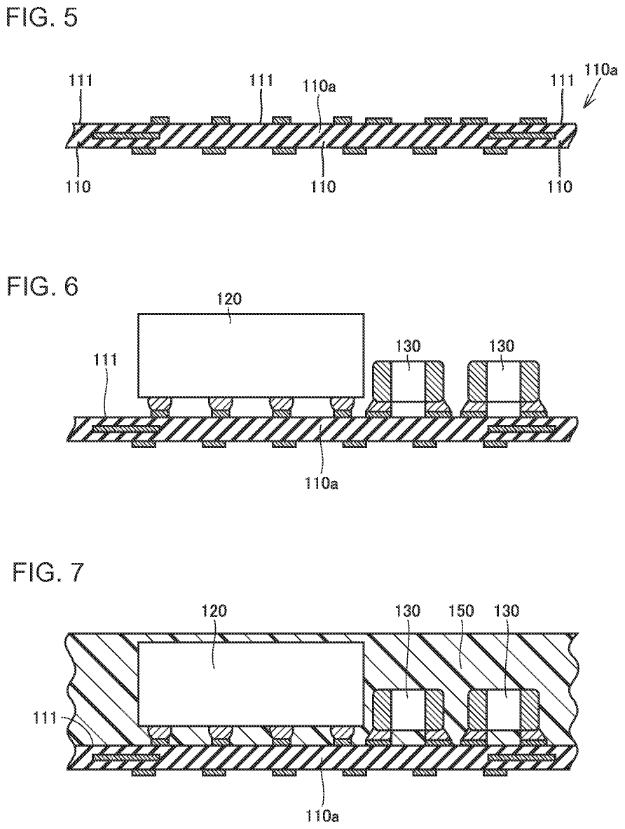

A method of manufacturing module 100 according to the first embodiment of the present disclosure will be described below. FIG. 5 is a cross-sectional view showing a state in which a substrate assembly is prepared in the method of manufacturing the module according to the first embodiment of the present disclosure. As shown in FIG. 5, a substrate assembly 110a is an assembly of substrates 110 included in respective modules 100. Substrate assembly 110a is an assembly of a plurality of substrates 110 connected to one another such that first surfaces 111 of the plurality of substrates 110 are contiguous to one another.

FIG. 6 is a cross-sectional view showing a state in which the first component and the like are mounted on the substrate assembly in the method of manufacturing the module according to the first embodiment of the present disclosure. As shown in FIG. 6, such components as first component 120 and second component 130 are mounted on first surface 111 of substrate assembly 110a. These components are mounted on first surface 111, for example, by printing a solder paste on first surface 111 and thereafter performing reflow soldering with the use of this solder paste. After these components are mounted on first surface 111, flux cleaning is performed.

FIG. 7 is a cross-sectional view showing a state in which the sealing resin is arranged on the first surface of the substrate assembly in the method of manufacturing the module according to the first embodiment of the present disclosure. As shown in FIG. 7, sealing resin 150 yet to be cured is provided on first surface 111 of substrate assembly 110a by molding. At this time, first component 120 and second component 130 mounted on first surface 111 are sealed with sealing resin 150 to completely be covered therewith. Thereafter, sealing resin 150 is cured by heating substrate assembly 110a provided with sealing resin 150 yet to be cured in an oven or the like. In an example where sealing resin 150 contains a filler, the filler is added to the resin component and they are kneaded in advance before sealing resin 150 is provided on first surface 111.

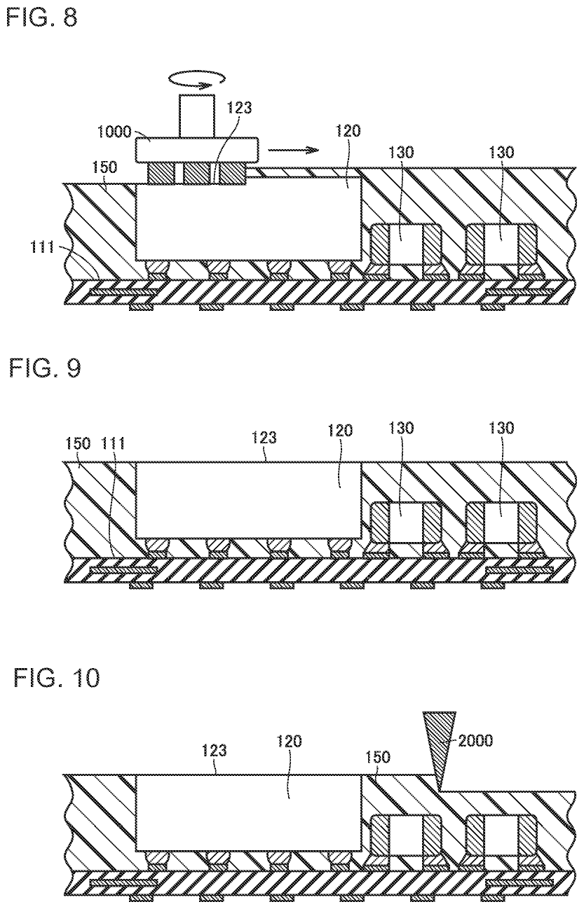

FIG. 8 is a cross-sectional view showing a state in which the sealing resin and the first component are being ground in the method of manufacturing the module according to the first embodiment of the present disclosure. FIG. 9 is a cross-sectional view showing a construction in a state in which the sealing resin and the first component have been ground in the method of manufacturing the module according to the first embodiment of the present disclosure. As shown in FIGS. 8 and 9, a portion of sealing resin 150 in a state in FIG. 7 which is located opposite to first surface 111 is ground by a grinding machine 1000. At this time, a portion of first component 120 on the side opposite to first surface 111 is also ground together with sealing resin 150. First component 120 is thus exposed through sealing resin 150 and planar portion 123 is formed in first component 120.

Sealing resin 150 and first component 120 are ground such that second component 130 is not exposed through sealing resin 150. Therefore, in an example where a maximum height of second component 130 is, for example, 300 [μm] in a direction orthogonal to first surface 111, a height of first component 120 yet to be ground should be set to 400 [μm], a height of sealing resin 150 yet to be ground should be set to 500 [μm], and the heights of ground first component 120 and ground sealing resin 150 should be set to 350 [μm].

Though grinding machine 1000 used in the grinding step described above is not particularly limited, it is, for example, a rotary grinding machine. More specifically, first component 120 and sealing resin 150 are ground by creep feed grinding or in-feed grinding with the use of a circular wheel provided with a grinding wheel. A grinding wheel obtained by solidifying hard particles such as diamond particles with a binder such as resin is employed as the grinding wheel.

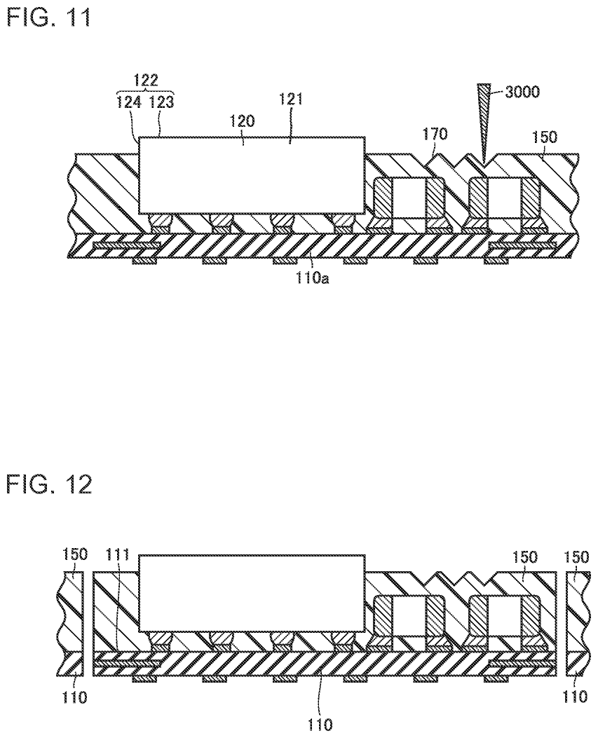

FIG. 10 is a cross-sectional view showing a state in which a surface of the sealing resin is further being ground away by laser in the method of manufacturing the module according to the first embodiment of the present disclosure. FIG. 11 is a cross-sectional view showing a state in which the marking portion is being provided in the surface of the sealing resin in the method of manufacturing the module according to the first embodiment of the present disclosure.

After first component 120 and sealing resin 150 are ground in the same step (see FIGS. 8 and 9), additionally, a part of sealing resin 150 is ground away by melting, evaporation, and scattering of the surface of sealing resin 150 by irradiation with first laser 2000 as shown in FIG. 10. Peripheral side portion 124 is thus formed, and accordingly, projecting portion 121 is formed (see FIG. 11).

Though first laser 2000 is, for example, green laser having a wavelength of 532 [nm], it may be infrared laser having a wavelength of 1064 [nm] or ultraviolet laser having a wavelength of 355 [nm]. The surface of sealing resin 150 may be ground away by another grinding method or buffing instead of first laser 2000.

A type of first laser 2000 may be switched depending on a portion of sealing resin 150 to be processed. Infrared laser having a wavelength of 1064 [nm] has high Si transmittance. Therefore, when infrared laser is adopted as first laser 2000 and Si is adopted as the main material for first component 120, in a region proximate to first component 120, first laser 2000 may damage wiring on a circuit surface of first component 120 located on a side of substrate assembly 110a. Therefore, the type of first laser 2000 may be switched to use as first laser 2000, green laser having a wavelength of 532 [nm] or ultraviolet laser having a wavelength of 355 [nm] which has low Si transmissivity in the region proximate to first component 120 and to use as first laser 2000, infrared laser having a wavelength of 1064 [nm] in regions other than that. When laser having a wavelength low in transmissivity through the main material for first component 120 is employed as first laser 2000, outer edge portion 122 may be formed by irradiating first component 120 with first laser 2000 to grind away a part of first component 120.

As shown in FIG. 11, marking portion 170 is then provided by providing a plurality of recesses in the surface of sealing resin 150 with the use of second laser 3000. Laser similar to first laser 2000 can be employed as second laser 3000. In an example where LiTaO₃ or LiNbO₃ is adopted as the main material for first component 120, marking portion 170 cannot be provided by second laser 3000 on first component 120 exposed through sealing resin 150, because second laser 3000 passes through LiTaO₃ or LiNbO₃ and damages wiring on the circuit surface of first component 120 located on the side of substrate assembly 110a.

Marking portion 170 does not have to be provided as the plurality of recesses. For example, first laser 2000 may grind the surface of sealing resin 150 to a substantially flat state, and thereafter ink may be provided on the substantially flat surface of sealing resin 150. In this case, the ink serves as marking portion 170. In the example where marking portion 170 is formed of ink, marking portion 170 is formed by applying epoxy resin by ink jet printing onto the surface of sealing resin 150 and thereafter curing the epoxy resin by irradiation with ultraviolet rays.

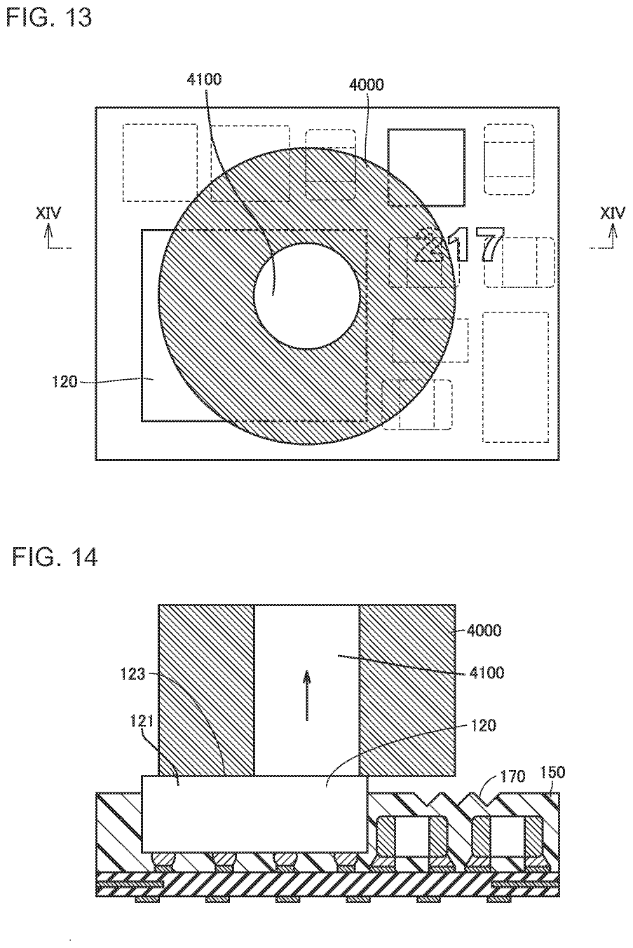

FIG. 12 is a cross-sectional view showing a state in which the substrate assembly is being diced in the method of manufacturing the module according to the first embodiment of the present disclosure. As shown in FIG. 12, substrate assembly 110a is diced into a plurality of substrates 110 as necessary by cutting with a dicer or the like. Accordingly, sealing resin 150 is also simultaneously cut and diced such that pieces of sealing resin 150 correspond to the plurality of substrates 110, respectively.

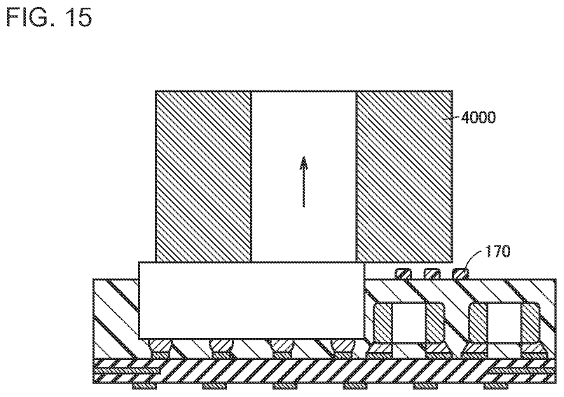

FIG. 13 is a plan view showing a state in which the module on which the shield film is yet to be formed is being moved in the method of manufacturing the module according to the first embodiment of the present disclosure. FIG. 14 is a cross-sectional view of a movement step in FIG. 13, along a direction shown with an arrow XIV-XIV.

As shown in FIGS. 13 and 14, when module 100 on which the shield film is yet to be formed is picked up with the use of a pick-up nozzle 4000, a nozzle hole 4100 in pick-up nozzle 4000 is closed by projecting portion 121 (planar portion 123) of first component 120 and the inside of nozzle hole 4100 is evacuated to set a negative pressure therein, so that pick-up nozzle 4000 is attracted by suction to projecting portion 121. Pick-up by pick-up nozzle 4000 is thus allowed. Accordingly, contact between marking portion 170 and pick-up nozzle 4000 can be suppressed. Lowering in visual recognizability of marking portion 170 due to rubbing or a flaw in marking portion 170 or a portion therearound in sealing resin 150 can thus be suppressed. A size of marking portion 170 can relatively be small owing to suppression of lowering in visual recognizability of marking portion 170.

FIG. 15 is a cross-sectional view showing the movement step in the example where the marking portion is formed of ink in the method of manufacturing the module according to the first embodiment of the present disclosure. As shown in FIG. 15, also in the example where marking portion 170 is formed of ink, contact between marking portion 170 and pick-up nozzle 4000 can be suppressed. Lowering in visual recognizability of marking portion 170 due to deformation of marking portion 170 or separation of marking portion 170 can thus be suppressed.

The module on which the shield film is yet to be formed is then moved to a metal tray or an adhesive sheet with the use of pick-up nozzle 4000 described above and aligned thereon. As shown in FIGS. 1, 2, and 4, shield film 160 is then formed on peripheral side surface 113 of substrate 110, first component 120, and sealing resin 150 by sputtering of metallic atoms to manufacture module 100.

At this time, metallic atoms are injected from a position on the side of first surface 111 when viewed from substrate 110, the position being sufficiently distant from module 100 as compared with the size of module 100. Therefore, impingement of metallic atoms on first component 120 and sealing resin 150 from a direction substantially perpendicular to first surface 111 forms shield film 160. Therefore, on planar portion 123, shield film 160 more readily grows than on peripheral side portion 124 and consequently shield film 160 is formed to a large thickness. In a portion of planar portion 123 in the vicinity of peripheral side portion 124, shield film 160 is hard to grow and hence it is formed to a relatively small thickness. Therefore, shield film 160 located on outer edge portion 122 of projecting portion 121 is in a shape as shown in FIG. 4. This tendency is more noticeable in an attempt to form shield film 160 to a thickness not larger than 10 [μm].

In an example where marking portion 170 is formed of ink on shield film 160, marking portion 170 is formed by application by ink jet printing and curing. In an example where marking portion 170 is composed of a plurality of recesses in shield film 160, marking portion 170 is provided by irradiation with laser. In this case, lowering in visual recognizability of the marking portion due to contact between marking portion 170 and the pick-up nozzle in movement of manufactured module 100 by the pick-up nozzle can be suppressed.

As set forth above, module 100 according to the first embodiment of the present disclosure includes substrate 110, first component 120, and sealing resin 150. Substrate 110 is provided with first surface 111. First component 120 is mounted on first surface 111. First component 120 is sealed with sealing resin 150 at least from the lateral side. First component 120 includes projecting portion 121. Projecting portion 121 projects from sealing resin 150 on the side opposite to substrate 110. Since first component 120 thus includes projecting portion 121 that projects from sealing resin 150, an area of a portion of the surface of first component 120 exposed through sealing resin 150 increases. Therefore, performance to radiate heat generated from first component 120 can further be improved.

Furthermore, for example, even when a surface acoustic wave filter or an IC of a power amplifier type which receives input of a great current which is a cause of increase in amount of heat generation is employed as first component 120, an amount of heat transfer from first component 120 to another component mounted on module 100 is relatively suppressed because heat radiation performance of first component 120 is improved. Therefore, a plurality of components including first component 120 can be mounted on module 100 in high density. Accordingly, module 100 can be reduced in size, and can suitably be mounted on a small device such as a smartphone for which miniaturization of internal wiring or integration of internal components is required in the field of wireless communication.

In the present embodiment, the main material for first component 120 is higher in thermal conductivity than the material for sealing resin 150. Performance to radiate heat from projecting portion 121 which is a part of first component 120 is thus further improved.

In the present embodiment, shield film 160 made of metal, shield film 160 covering first component 120 and sealing resin 150, is further provided. Shield film 160 is in contact with projecting portion 121. As a result of such contact, heat is more readily transferred from projecting portion 121 to shield film 160, and owing to the shape of projecting portion 121, an area of contact between first component 120 and shield film 160 is also relatively large. Therefore, heat radiated from projecting portion 121 is further readily radiated from shield film 160 to the outside. Accordingly, heat radiation performance of module 100 as a whole is further improved.

In the present embodiment, shield film 160 contains an alloy containing at least one element selected from among Ti, Cr, Co, Ni, Fe, Cu, Ag, and Au. When shield film 160 contains such an alloy, performance to shield components such as first component 120 mounted on first surface 111 is ensured, and heat radiated from projecting portion 121 is further radiated from shield film 160 to the outside.

In the present embodiment, marking portion 170 provided as being visually recognizable at the position different from first component 120 when module 100 is viewed from the side of first surface 111 is further provided. Even when module 100 is further provided with such a marking portion 170, module 100 or an article to be module 100 can be picked up by using projecting portion 121 or a portion of shield film 160 in contact with projecting portion 121 without touching marking portion 170 or a portion adjacent thereto. Therefore, deformation of marking portion 170 due to contact of marking portion 170 and a portion therearound with a pick-up device can be suppressed, and accordingly lowering in visual recognizability of marking portion 170 can be suppressed.

### Second Embodiment

A module according to a second embodiment of the present disclosure will be described below. The module according to the second embodiment of the present disclosure is different from module 100 according to the first embodiment of the present disclosure mainly in shape of the projecting portion. Therefore, description of the construction similar to that of module 100 according to the first embodiment of the present disclosure will not be repeated.

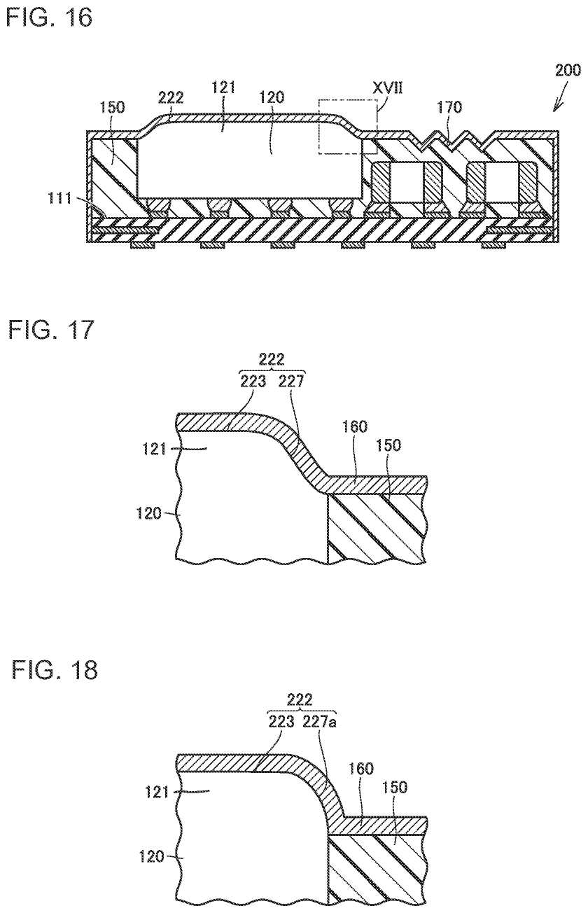

FIG. 16 is a cross-sectional view showing the module according to the second embodiment of the present disclosure. FIG. 17 is a partial cross-sectional view showing a construction in a region XVII in FIG. 16. As shown in FIGS. 16 and 17, an outer edge portion 222 is rounded when viewed in a cross-section along the plane perpendicular to first surface 111. Therefore, in forming shield film 160 on outer edge portion 222 by sputtering from one direction (for example, the direction perpendicular to first surface 111), uniformity in thickness of shield film 160 can be improved as compared with module 100 according to the first embodiment. Therefore, cutting by projecting portion 121, of a portion relatively small in thickness of shield film 160 that covers projecting portion 121 while the shield film is in contact with projecting portion 121 is suppressed. Since a volume of shield film 160 can be increased while increase in average thickness of shield film 160 is suppressed, a cross-sectional area of a heat radiation path in shield film 160 in the direction orthogonal to the direction of thickness can relatively be increased. Accordingly, heat radiation performance of a module 200 owing to projecting portion 121 and shield film 160 is further improved.

Since outer edge portion 222 has a roughened surface, glossiness of outer edge portion 222 is relatively low. As the glossiness of outer edge portion 222 is relatively low, difference in brightness between outer edge portion 222 and sealing resin 150 becomes small. Since marking portion 170 is visually recognized or read based on the difference in brightness between a bright portion and a dark portion in marking portion 170, visual recognizability of marking portion 170 is higher when the difference in brightness between outer edge portion 222 and sealing resin 150 is smaller than the difference in brightness between the bright portion and the dark portion in marking portion 170. In reading marking portion 170 with a prescribed device, a frequency of occurrence of an error in reading of marking portion 170 can be lowered. Arithmetic mean roughness (Ra) of outer edge portion 222 is, for example, not less than 0.15 [μm] and not more than 0.95 [μm].

In the present embodiment, outer edge portion 222 is further provided with a curved portion 227. Curved portion 227 is located as being connected to an outer edge of a planar portion 223. Curved portion 227 is smoothly contiguous to planar portion 223 when viewed in a cross-section along the plane perpendicular to first surface 111. Furthermore, curved portion 227 is smoothly contiguous to the surface of sealing resin 150 in contact with shield film 160 when viewed in the cross-section along the plane perpendicular to first surface 111.

The curved portion is not limited to the shape described above. FIG. 18 is a partial cross-sectional view of a module according to a modification of the second embodiment of the present disclosure. The partially enlarged view of the modification of the second embodiment shown in FIG. 18 corresponds to the partially enlarged view of the second embodiment shown in FIG. 17. As shown in FIG. 18, in the present modification, a curved portion 227a is curved convexly toward shield film 160. Curved portion 227a is smoothly contiguous to a surface portion of first component 120 in contact with sealing resin 150 when viewed in a cross-section along the plane perpendicular to first surface 111. The present modification can also achieve improvement in uniformity in thickness of shield film 160 similarly to the second embodiment of the present disclosure.

A method of manufacturing module 200 according to the second embodiment of the present disclosure will be described below. The method of manufacturing module 200 includes a step of working by wet blasting instead of the step of grinding away sealing resin 150 with first laser 2000 in the method of manufacturing module 100 according to the first embodiment of the present disclosure.

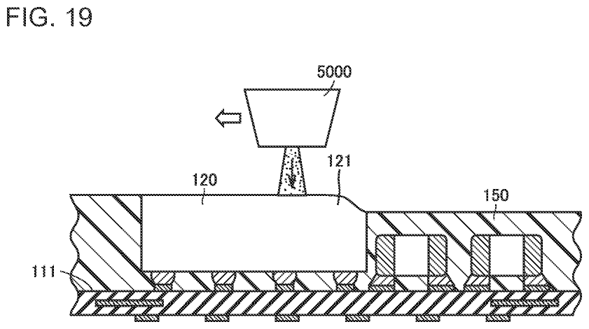

FIG. 19 is a cross-sectional view showing a wet blasting step after a grinding step in the method of manufacturing the module according to the second embodiment of the present disclosure. As shown in FIG. 19, projecting portion 121 of first component 120 is worked to a desired shape by grinding away the surface of sealing resin 150 and first component 120 with the use of an injection nozzle 5000.

Examples of slurry to be injected in wet blasting include a mixture obtained by mixing alumina (Al₂O₃) abrasive grains in water. For example, precision polishing microgrits having a grain size of #600 and defined under JIS standard (JIS6001-2 (2017)) can be employed as alumina abrasive grains, and a concentration of alumina in the slurry is not lower than 10 [wt %] and not higher than 20 [wt %]. The slurry is injected as being mixed with compressed air at a pressure not lower than 0.1 [MPa] and not higher than 0.4 [MPa]. Though first component 120 is harder to be ground than sealing resin 150, projecting portion 121 can be formed to a desired shape by controlling a pressure of compressed air and a time period for injection at each portion of injection. The time period for injection is controlled by adjusting a time period for movement at each portion of injection while injection nozzle 5000 is moved in parallel to first surface 111 or adjusting the number of times of injection at each portion of injection. Curved portion 227 in the shape as shown in FIG. 17 is formed by simultaneously injecting slurry toward sealing resin 150 around first component 120 and toward first component 120 around sealing resin 150. By thus performing wet blasting, the surface of outer edge portion 222 is roughened.

Instead of wet blasting, dry blasting in which alumina powders are injected over compressed air directly toward first component 120 and sealing resin 150 may be performed, or another polishing and grinding method such as buffing may be used. After buffing, wet blasting or dry blasting may be performed. After the wet blasting step, a cleaning step may be performed. The cleaning step may include a plurality of steps, and may include, for example, plasma cleaning with the use of inert gas such as Ar. In Ar plasma cleaning, first component 120 is harder to be ground than sealing resin 150 because of a difference in rate of etching by Ar plasma, and hence a secondary effect of the wet blasting step can also be expected. In an example where the main material for first component 120 is a polycrystalline body or an amorphous body such as glass, outer edge portion 222 of first component 120 may be treated by chemical etching after the wet blasting step and before the cleaning step. Outer edge portion 222 of first component 120 is thus readily roughened to desired roughness.

### Third Embodiment

A module according to a third embodiment of the present disclosure will be described below. The module according to the third embodiment of the present disclosure is different from module 100 according to the first embodiment of the present disclosure mainly in including a metallic wall portion. Therefore, description of the construction similar to that of module 100 according to the first embodiment of the present disclosure will not be repeated.

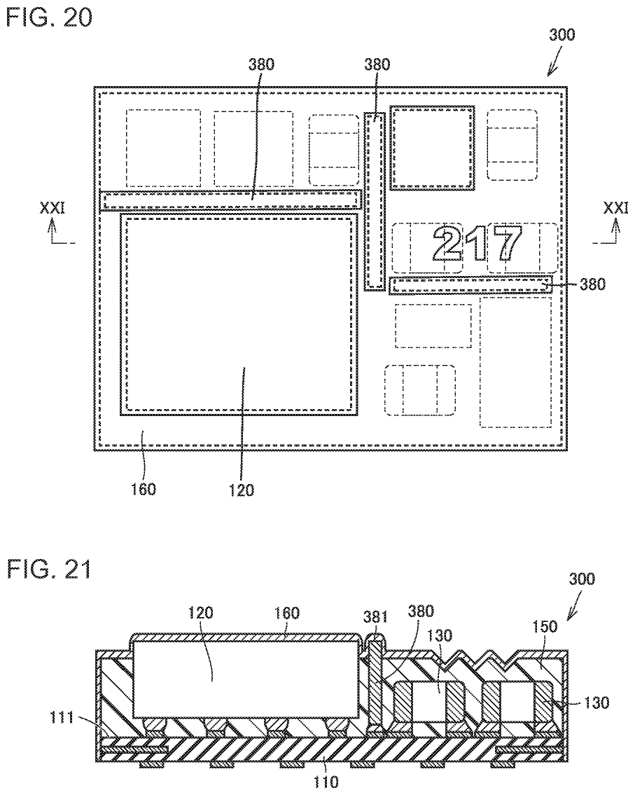

FIG. 20 is a plan view showing the module according to the third embodiment of the present disclosure. FIG. 21 is a cross-sectional view of the module in FIG. 20, along a direction shown with an arrow XXI-XXI. As shown in FIGS. 20 and 21, a module 300 according to the present embodiment further includes a metallic wall portion 380. Metallic wall portion 380 is mounted on first surface 111 and located adjacently to first component 120 with at least sealing resin 150 being interposed. Metallic wall portion 380 is provided with an end edge portion 381 that projects from sealing resin 150 on the side opposite to substrate 110. Heat generated from first component 120 is thus transferred to metallic wall portion 380 and radiated from end edge portion 381. In other words, there are more paths for radiation of heat generated from first component 120 and performance to radiate heat generated from first component 120 can further be improved.

Metallic wall portion 380 is in a form of a plate and extends in the direction orthogonal to first surface 111. A material higher in thermal conductivity than the material for sealing resin 150 is employed as the material for metallic wall portion 380. Though metallic wall portion 380 is composed, for example, of Cu, it may be made of stainless steel.

In the present embodiment, shield film 160 covers metallic wall portion 380 as being in contact with end edge portion 381. Heat is thus readily transferred from end edge portion 381 to shield film 160 and heat radiated from end edge portion 381 is more readily radiated from shield film 160 to the outside. Accordingly, heat radiation performance of module 300 as a whole is further improved. Furthermore, electrical connection of metallic wall portion 380 to shield film 160 or ground electrode 114 of substrate 110 can prevent electromagnetic waves generated from first component 120 from propagating to second component 130 and shielding performance of module 300 as a whole can also be improved.

A method of manufacturing module 300 according to the third embodiment of the present disclosure will now briefly be described. Metallic wall portion 380 is mounted by soldering, in mounting first component 120 and the like in the method of manufacturing the module according to the first embodiment of the present disclosure. In the step of grinding first component 120 and sealing resin 150, a side of metallic wall portion 380 opposite to substrate 110 is ground. First component 120 and metallic wall portion 380 are thus substantially equal in length to each other in the direction orthogonal to first surface 111.

When first component 120 and sealing resin 150 are covered with shield film 160 by sputtering, at the same time, end edge portion 381 of metallic wall portion 380 is also covered with shield film 160. End edge portion 381 and shield film 160 are thus in intimate contact with each other.

### Fourth Embodiment

A module according to a fourth embodiment of the present disclosure will be described below. The module according to the fourth embodiment of the present disclosure is different from module 200 according to the second embodiment of the present disclosure mainly in including a metallic wall portion similar to metallic wall portion 380 in the third embodiment. Therefore, description of the construction similar to that of module 200 according to the second embodiment of the present disclosure and metallic wall portion 380 according to the third embodiment will not be repeated.

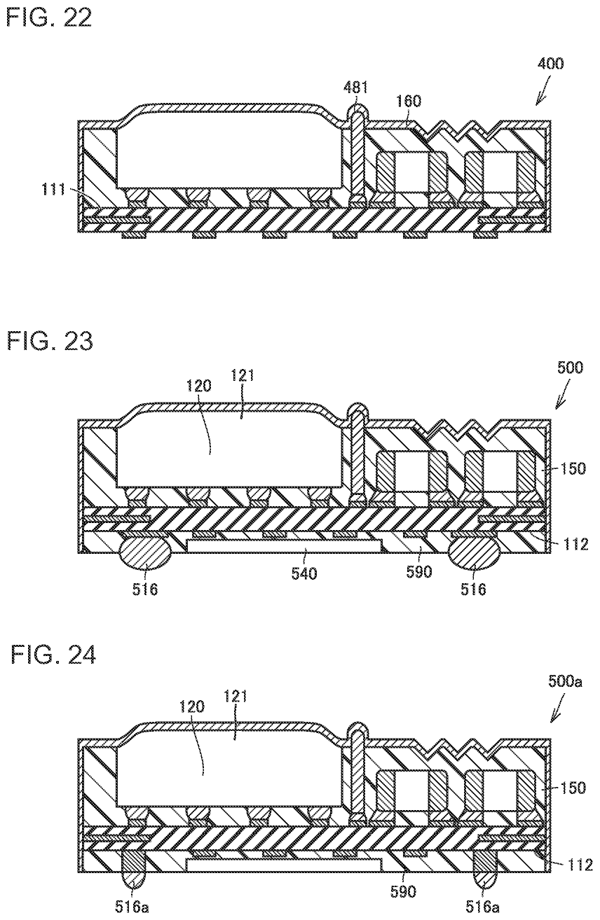

FIG. 22 is a cross-sectional view showing the module according to the fourth embodiment of the present disclosure. As shown in FIG. 22, in the present embodiment, an end edge portion 481 is rounded when viewed in a cross-section along the plane perpendicular to first surface 111. When shield film 160 is formed on such end edge portion 481 by sputtering from one direction (for example, the direction perpendicular to first surface 111) in a process of manufacturing of a module 400, uniformity in thickness of shield film 160 can be improved as compared with module 300 according to the third embodiment. Therefore, cutting by end edge portion 481, of shield film 160 that covers end edge portion 481 while the shield film is in contact with end edge portion 481 is suppressed. Furthermore, a volume of shield film 160 can be increased. Accordingly, heat radiation performance of module 400 owing to end edge portion 481 and shield film 160 is further improved.

### Fifth Embodiment

A module according to a fifth embodiment of the present disclosure will be described below. The module according to the fifth embodiment of the present disclosure is different from module 200 according to the second embodiment of the present disclosure mainly in that a component is mounted also on a side of the second surface of the substrate. Therefore, description of the construction similar to that of module 200 according to the second embodiment of the present disclosure will not be repeated.

FIG. 23 is a cross-sectional view showing the module according to the fifth embodiment of the present disclosure. As shown in FIG. 23, in a module 500 according to the present embodiment, a third component 540 is mounted on the side of second surface 112. Third component 540 is, for example, an IC. Separately from (first) sealing resin 150, a second sealing resin 590 is also provided on the side of second surface 112. A second external terminal 516 provided on the side of second surface 112 is exposed through second sealing resin 590. Second external terminal 516 provided on the side of second surface 112 is, for example, a solder bump.

Second external terminal 516 is not limited to the construction described above. FIG. 24 is a cross-sectional view showing a module according to a modification of the fifth embodiment of the present disclosure. As shown in FIG. 24, in a module 500a according to the present modification, a second external terminal 516a provided on the side of second surface 112 includes a rod-shaped electrode and a solder bump. The rod-shaped electrode (I/O pin) is exposed through the second sealing resin. The solder bump is connected onto the rod-shaped electrode exposed through the second sealing resin.

In module 500 according to the fifth embodiment of the present disclosure and module 500a according to the modification thereof as well, first component 120 includes projecting portion 121 that projects from (first) sealing resin 150, so that an area of a portion of the surface of first component 120 which is exposed through (first) sealing resin 150 increases. Performance to radiate heat generated form first component 120 can thus further be improved.

### Sixth Embodiment

A module according to a sixth embodiment of the present disclosure will be described below. The module according to the sixth embodiment of the present disclosure is different from module 100 according to the first embodiment of the present disclosure mainly in that there is a region not sealed with the sealing resin in the first surface of the substrate. Therefore, description of the construction similar to that of module 100 according to the first embodiment of the present disclosure will not be repeated.

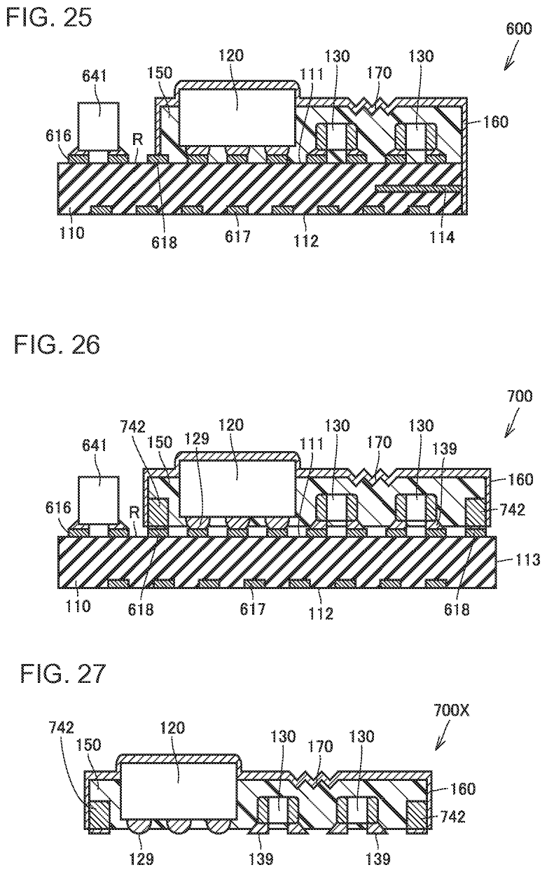

FIG. 25 is a cross-sectional view showing the module according to the sixth embodiment of the present disclosure. As shown in FIG. 25, in a module 600 according to the present embodiment, in first surface 111 of substrate 110, there is a region R partially not covered with sealing resin 150. In region R, an electrode 616 is formed and a fourth component 641 is mounted with electrode 616 being interposed. Fourth component 641 is, for example, a connector. In region R, a plurality of fourth components 641 may be mounted, or fourth component 641 may be a component other than the connector, which cannot be sealed with sealing resin 150, such as a sensor.

Substrate 110 is provided with an antenna 617. Antenna 617 may be formed on second surface 112 of substrate 110 or may be provided near second surface 112 in the inside of substrate 110. A second ground electrode 618 is provided on first surface 111 of substrate 110. Second ground electrode 618 is in contact with shield film 160.

In a method of manufacturing module 600 according to the sixth embodiment of the present disclosure, in an example where transfer molding, for example, is adopted as a method of molding sealing resin 150, region R should only be provided by molding sealing resin 150 in a mold constructed such that resin does not flow into a partial region in first surface 111 of substrate 110. In a roughening step, region R not covered with sealing resin 150 should be protected in advance so as not to be roughened. A method of protection may be, for example, a method of covering region R with a cover before the roughening step.

### Seventh Embodiment

A module according to a seventh embodiment of the present disclosure will be described below. The module according to the seventh embodiment of the present disclosure is different from the module according to the sixth embodiment of the present disclosure mainly in further including a shield connection member. Therefore, description of the construction similar to that of module 600 according to the sixth embodiment of the present disclosure will not be repeated.

FIG. 26 is a cross-sectional view showing the module according to the seventh embodiment of the present disclosure. As shown in FIG. 26, a module 700 according to the seventh embodiment of the present disclosure further includes a shield connection member 742. Shield connection member 742 is connected to second ground electrode 618 provided on first surface 111 of substrate 110. Shield connection member 742 is in contact with shield film 160 on an inner side of shield film 160. Shield film 160 is thus electrically connected to second ground electrode 618 with shield connection member 742 being interposed.

In module 700 according to the seventh embodiment of the present disclosure, a bonding portion (corresponding to solder bump 129) of first component 120 and a bonding portion (corresponding to solder 139) of second component 130 are exposed at a lower surface of sealing resin 150. Shield film 160 is not in contact with peripheral side surface 113.

Module 700 according to the seventh embodiment of the present disclosure shown in FIG. 26 can be manufactured, for example, by mounting an assembly which will be described below and fourth component 641 on substrate 110. FIG. 27 is a cross-sectional view showing an exemplary assembly used in manufacturing of the module according to the seventh embodiment of the present disclosure. Module 700 according to the seventh embodiment of the present disclosure can be manufactured by mounting an assembly 700X shown in FIG. 27 on first surface 111 of substrate 110 together with fourth component 641 (see FIG. 26). In FIG. 27, a corresponding element of module 700 in assembly 700X has the same reference character allotted.

Assembly 700X does not include wiring that electrically connects first component 120 and second component 130 to each other. The wiring that connects first component 120 and second component 130 to each other is provided in substrate 110 on which assembly 700X is mounted. Components of assembly 700X are electrically connected to one another by mounting assembly 700X on substrate 110. Assembly 700X can be manufactured by the manufacturing method similar to the method of manufacturing module 100 according to the first embodiment of the present disclosure except for providing assembly 700X on a temporary carrier instead of the substrate. In other words, assembly 700X is provided on the temporary carrier and thereafter the temporary carrier is removed from assembly 700X, to thereby manufacture assembly 700X.

Features that can be combined in the description of the embodiments above may be combined with each other.

It should be understood that the embodiments disclosed herein are illustrative and non-restrictive in every respect. The scope of the present disclosure is defined by the terms of the claims rather than the description above and is intended to include any modifications within the scope and meaning equivalent to the terms of the claims.
100, 200, 300, 400, 500, 500a, 600, 700 module; 110 substrate; 110a substrate assembly; 111 first surface; 112 second surface; 113 peripheral side surface; 114 ground electrode; 115 external terminal; 120 first component; 121 projecting portion; 122, 222 outer edge portion; 123, 223 planar portion; 124 peripheral side portion; 129 solder bump; 130 second component; 139 solder; 150 sealing resin; 160 shield film; 170 marking portion; 227, 227a curved portion; 380 metallic wall portion; 381, 481 end edge portion; 516, 516a second external terminal; 540 third component; 590 second sealing resin; 616 electrode; 617 antenna; 618 second ground electrode; 641 fourth component; 700X assembly; 742 shield connection member; 1000 grinding machine; 2000 first laser; 3000 second laser; 4000 pick-up nozzle; 4100 nozzle hole; 5000 injection nozzle

1. A module comprising:
a substrate having a first surface;
a first component mounted on the first surface; and
a sealing resin sealing the first component at least from a lateral side, wherein
the first component includes a projecting portion projecting from the sealing resin on a side opposite to a side of the substrate.

2. The module according to claim 1, wherein
a main material for the first component is higher in thermal conductivity than a material for the sealing resin.

3. The module according to claim 1, further comprising a shield film made of metal, the shield film covering the first component and the sealing resin, wherein
the shield film is in contact with the projecting portion.

4. The module according to claim 3, wherein
the projecting portion has an outer edge portion rounded when viewed in a cross-section along a plane perpendicular to the first surface.

5. The module according to claim 3, wherein
the shield film contains an alloy containing at least one element selected from among Ti, Cr, Co, Ni, Fe, Cu, Ag, and Au.

6. The module according to claim 1, further comprising a metallic wall portion mounted on the first surface and located adjacently to the first component with the sealing resin being interposed, wherein
the metallic wall portion has an end edge portion projecting from the sealing resin on the side opposite to the side of the substrate.

7. The module according to claim 3, further comprising a metallic wall portion mounted on the first surface and located adjacently to the first component with the sealing resin being interposed, wherein
the metallic wall portion has an end edge portion projecting from the sealing resin on the side opposite to the side of the substrate,
the end edge portion is rounded when viewed in a cross-section along a plane perpendicular to the first surface, and
the shield film covers the metallic wall portion as being in contact with the end edge portion.

8. The module according to claim 1, further comprising a marking portion provided as being visually recognizable at a position different from the first component when the module is viewed from a side of the first surface.

9. The module according to claim 3, wherein
the projecting portion has an outer edge portion including a portion extending diagonally to the first surface.

10. The module according to claim 9, wherein
the portion of the outer edge portion extending diagonally is rounded.

11. The module according to claim 9, wherein
the first component further includes a peripheral side surface located near the projecting portion, wherein the peripheral side surface is in contact with the sealing resin, and extends in a direction substantially perpendicular to the first surface.

12. The module according to claim 9, wherein
the outer edge portion extends in a direction substantially perpendicular or substantially in parallel to the first surface, near a boundary between the projecting portion and the sealing resin.

13. The module according to claim 9, wherein
the outer edge portion extends from a boundary between the projecting portion and the sealing resin as concavely curved with respect to the shield film.

14. The module according to claim 13, wherein
the outer edge portion extends substantially in parallel to the first surface, near the boundary.

15. The module according to claim 13, wherein
the outer edge portion extends from the boundary as concavely curved with respect to the shield film and thereafter extends as convexly curved with respect to the shield film.

16. The module according to claim 15, wherein
the outer edge portion extends substantially in parallel to the first surface, near the boundary.

17. The module according to claim 9, wherein
the outer edge portion extends from a boundary between the projecting portion and the sealing resin as convexly curved with respect to the shield film.

18. The module according to claim 17, wherein
the outer edge portion extends substantially perpendicularly to the first surface, near the boundary between the projecting portion and the sealing resin.
